(19) United States
(12) Patent Application Publication
(10) Pub. No.: US 2026/0112886 A1
(43) Pub. Date: Apr. 23, 2026

(54) SYSTEMS AND METHODS FOR OPERATING AN OVERHEAD ELECTRICAL LINE

(71) Applicant: CTC Global Corporation, Irvine, CA (US)

(72) Inventors: Kevin Corbalis, Tustin, CA (US); Eric Bosze, San Diego, CA (US); David Goekjian, Anaheim, CA (US)

(21) Appl. No.: 19/117,340

(22) PCT Filed: Oct. 2, 2023
(86) PCT No.: PCT/US2023/075733

§ 371 Date: Mar. 31, 2025

Related U.S. Application Data
(60) Provisional application No. 63/412,270, filed on Sep. 30, 2022.

(51) Int. Cl. H02H 7/22; H01B 7/18; H02G 1/02

(52) U.S. Cl. CPC H02H 7/226; H02G 1/02; H01B 7/18

(57) ABSTRACT

Systems and methods for the determination of a health index associated with an overhead electrical cable having a fiber-reinforced composite strength member and an electrical conductor surrounding the fiber-reinforced composite strength member. Operational data is collected from the electrical cable during operation of the cable and that data is utilized to update the health index over time. The updated health index may be utilized to estimate the remaining useful lifetime of the overhead electrical cable on a continuous basis.

### FIELD

This disclosure relates to the field of overhead electrical lines, particularly systems and methods for the operation and management of overhead electrical lines.

### DESCRIPTION OF THE DRAWINGS

FIG. 1 illustrates a portion of an overhead electrical transmission line.

FIG. 2 illustrates a cross-sectional view of an assembled dead-end termination apparatus.

FIG. 3 illustrates a perspective view of an assembled and crimped dead-end termination apparatus.

FIG. 4 illustrates a splice that is useful for connecting two electrical cable segments.

FIGS. 5A and 5B illustrate overhead electrical cables including fiber-reinforced composite strength members.

FIGS. 6A and 6B illustrate cross-sectional views of fiber-reinforced composite strength members incorporating optical fibers.

FIG. 7 illustrates a perspective view of an overhead electrical cable incorporating an optical fiber.

FIG. 8 illustrates a system for the operation of an electrical line according to an embodiment of the present disclosure.

### BACKGROUND

Electrical lines, e.g., overhead transmission lines and overhead distribution lines, transport electricity from point to point within an electrical grid. For example, high voltage transmission lines are used to transport electricity from a power plant to a substation, where a transformer reduces the electrical voltage so that the electricity may then be safely delivered to end users, e.g., using distribution lines.

Overhead electrical lines span many kilometers and require a great deal of capital expense to construct. In most cases, an operator relies upon the electrical lines to have a useful lifetime of 40 years. Thus, if an incident occurs that affects the useful lifetime of the electrical cable, the operator may not know that the incident even occurred, and even with that knowledge may not be able to determine the degree to which the incident diminished the useful lifetime of the overhead electrical cable.

### SUMMARY

Operators of overhead electrical lines, e.g., distribution lines and/or transmission lines, must know when an overhead electrical cable in the electrical line is at or near its expected lifetime. While an operator may know what the expected lifetime of the electrical cable is upon installation, operational activities may occur during operation that shorten the initial expected lifetime. If an operator, e.g., a utility company, continues to operate an electrical line that has degraded over time there is a risk that the overhead electrical cable will fail.

It would be useful to provide the operator of the electrical line with updated information regarding the expected lifetime as the electrical line is in use. In this way, the operator will be aware if certain operational activities, such as an increase in operating temperature for a period of time, have caused a meaningful decrease in the expected lifetime.

In one embodiment of the present disclosure, a method for the determination of an aging index is disclosed, where the aging index is associated with an overhead electrical line that is operatively strung onto support towers. The overhead electrical line includes at least a first overhead electrical cable having a fiber-reinforced composite strength member and an electrical conductor surrounding the fiber-reinforced composite strength member. The method includes the steps of: determining first temperature data associated with the first overhead electrical cable, the first temperature data comprising a first temperature value; determining first time period data associated with the first temperature data, the first time period data comprising the approximate amount of time that the electrical cable is exposed to the first temperature value; and determining a first updated aging index value from a prior aging index value, the first temperature data and the first time period data.

The foregoing method is subject to a number of refinements and characterizations. For example, upon determining that the first updated aging index value exceeds an acceptable aging index value, a system alert may be provided to an operator. The alert may encompass a sensory warning to an operator, such as a audible alarm and/or a visual indicator. In one characterization, the system alert is provided on a graphical user interface, e.g., on the screen of a computerized device such as a personal computer, a tablet or a cell phone.

In another refinement, an operator may take one or more steps in response to the determination of the first updated aging index value. In one characterization, upon determining that the first updated aging index value exceeds an acceptable aging index value, an operator may change an electrical parameter associated with the first overhead electrical cable. For example, the electrical parameter that may be changed is the electrical current flowing through the first overhead electrical cable. In one characterization, the step of changing the electrical current flowing through the first overhead cable includes stopping any electrical current flowing through the overhead electrical cable. In another characterization, the step of stopping the electrical current flowing through the first overhead electrical cable comprises shunting at least a portion of the electrical current from the first overhead electrical cable to a second overhead electrical cable. In another characterization, upon determining that the first updated aging index value exceeds an acceptable aging index value, an operational limit on the overhead electrical cable is updated. For example, the updated operational limit may be a limit on the current flowing through the overhead electrical cable or the temperature of the overhead electrical cable.

In another refinement, the fiber-reinforced strength member comprises reinforcing fibers in a polymer matrix. The polymer matrix may be a thermoplastic matrix or a thermoset matrix. In the case of a thermoset matrix, the thermoset polymer may have a glass transition temperature (T_{g}) of at least about 150° C. In another characterization, the fiber-reinforced strength member includes reinforcing fibers in a metal matrix. In another characterization, irrespective of the matrix material, the fiber-reinforced strength member comprises elongate reinforcing fibers in a matrix. In one refinement, the elongate reinforcing fibers comprise carbon fibers.

In another characterization, the first overhead electrical cable has a length of at least about 20 meters. In one refinement, the overhead electrical cable has a length of at least about 250 meters.

In another characterization, the prior aging index value is a base aging index value that is calculated before obtaining the first temperature data. The temperature data may be collected in a number of ways. In one characterization, the step of determining the first temperature data includes calculating the first temperature value from a known amperage in the first overhead electrical cable. In another characterization, the step of determining the first temperature data includes obtaining the first temperature value from a non-distributed sensor. In yet another characterization, the step of determining the first temperature data includes obtaining the first temperature value from a distributed temperature sensor associated with the overhead electrical cable. In one refinement, the step of determining the first temperature data includes obtaining first distributed temperature data from a first temperature sensing element that extends along a length of the first overhead electrical cable. In another refinement, the first temperature sensing element comprises a first optical fiber. For example, the first optical fiber may be a glass optical fiber. In one construction, the first optical fiber is embedded in the fiber-reinforced composite strength member. In another construction, the first optical fiber is affixed to an outer surface of the fiber-reinforced composite strength member.

In another characterization, the step of obtaining the distributed temperature data from a first temperature sensing element comprises interrogating the first temperature sensing optical fiber using an OTDR device that is operatively connected to the first optical fiber.

In another characterization, the first temperature data includes a first time associated with the determination of the first temperature value. In one refinement, the method also includes the step of determining second temperature data associated with the first overhead electrical cable, the second temperature data comprising a second temperature value and a second time associated with the second temperature value, wherein the second time is after the first time. In a further refinement, the step of determining first time period data includes calculating a time period from the first time associated with the first temperature value and from the second time associated with the second temperature value. The step of determining the second temperature data may include obtaining second distributed temperature data from a temperature sensing element that extends along a length of the first overhead electrical cable, where the temperature sensing element is an optical fiber. In one refinement, the temperature sensing element used to obtain the second distributed temperature data is the same temperature sensing element as the first temperature sensing element.

In another characterization, the first updated aging index value is determined by extrapolating data from a pre-determined baseline data point and a first updated data point that is calculated using the first temperature data and the first time period data. In one refinement, the first updated data point is calculated using an exponential equation of the form:

$$y = {Ae}^{( B \cdot x )}$$

$$where :$$

$$e = 2.718 ( Euler ’ s number )$$

$$y = time ( hours ) ;$$

$$A = time ( hours ) , a pre - exponential factor that is a real number ;$$

$$B = represents the degradation energy with temperature ;$$

$$x = 1 / T , where T is temperature in Kelvin .$$

In another characterization, the first updated aging index value is determined from a reference data table.

In yet another characterization, the method includes determining third temperature data associated with the first overhead electrical cable, the third temperature data including a third temperature value and a third time associated with the third temperature value, and determining a third updated aging index value from the second updated aging index value and the third temperature data.

It will be appreciated that the foregoing characterizations and refinements may be implemented independently or in any combination.

In another embodiment, a method for enabling an operator to prospectively determine if taking a particular action, e.g., increasing or decreasing the power supplied to an electrical line, will adversely affect the expected lifetime of the electrical line. The method includes the steps of ascertaining a planned operating temperature and a planned operating time period for the planned operating temperature for the first overhead electrical cable, and determining an updated health index for the first overhead electrical cable based upon a prior health index, the planned operating temperature and the planned operating time period.

These and other embodiments of the present disclosure will become apparent to those of skill in the art from the following description.

### DESCRIPTION

This disclosure relates to systems and methods for the operation of an overhead electrical line. As used herein, the term overhead electrical line encompasses both overhead transmission lines and overhead distribution lines. Transmission lines are electrical lines that are configured to carry relatively high voltage electricity, e.g., about 60 kV or greater, over long distances such as from a power generation source to a substation, where transformers are used to decrease the voltage from the transmission line and supply electricity to one or more distribution lines with the lower voltage electricity. Thus, distribution lines are overhead electrical lines that are configured to distribute lower voltage electricity, e.g., less than about 60 KV, on a more localized basis such as from a substation to surrounding communities, e.g., to residential and commercial neighborhoods. In either event, the overhead electrical lines include long electrically conducting cables that are supported above the ground by a series of support towers, sometimes referred to as pylons. As is described below, overhead electrical lines also include other critical components such as hardware for attaching the electrical cables to the support towers and insulators for preventing the leakage of electrical current from the electrical cables to the underlying terrain.

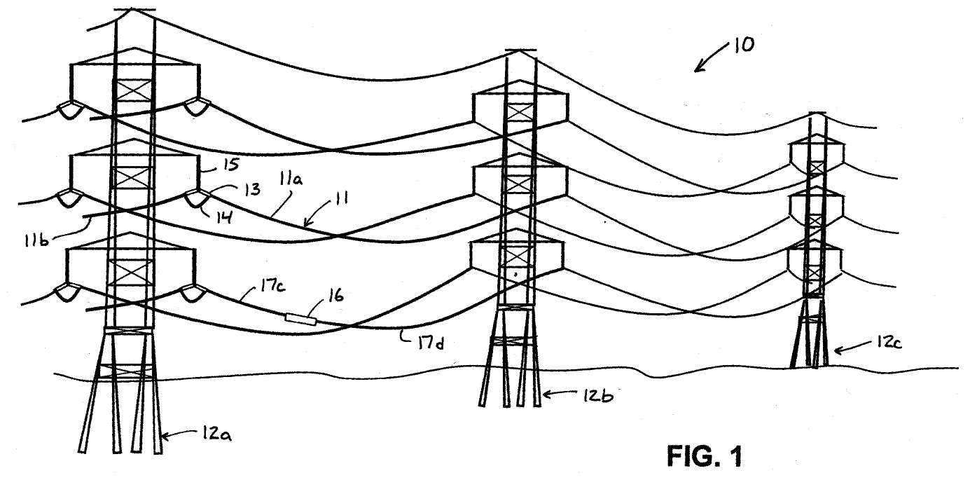

FIG. 1 illustrates such an overhead electrical line 10, specifically an overhead transmission line. Although the following description is directed primarily to systems and methods for the operation of a transmission line, it is to be understood that the systems and methods may similarly be employed with distribution lines, either separately from a transmission line or in combination with a transmission line. The transmission line 10 includes electrical cables, e.g., electrical cable 11, that conduct electricity and that are supported above the terrain by two or more support towers such as support towers 12a/12b/12c. The electrical cables may have a length of at least about 20 meters, such as at least about 250 meter, such as at least about 500 meter or even one kilometer.

Nonetheless, transmission lines may span many kilometers, requiring extremely long lengths of joined electrical cables. As a result, the electrical line is typically comprised of two or more electrical cable segments that are mechanically and electrically joined to form a continuous electrical pathway along the transmission line. Further, a transmission line includes a plurality of spaced-apart electrical cables, typically in groups of three, to support the transmission of alternating current (AC) in three phases.

As noted above, one function of the support towers is to safely elevate the electrical cables above the terrain. In this regard, the electrical cables are attached to the support towers using different types of hardware. Some of the support towers are referred to as dead-end towers or anchor towers, such as dead-end tower 12a. Such towers are located at termination points, e.g., at substations or at locations where the electrical line is routed underground. Dead-end towers such as dead-end tower 12a may also be required where the electrical line changes direction, e.g., makes a turn, crosses a roadway or other structure where there is a high risk of damage or injury if the electrical cable fails, or at regular intervals in a long straight path. In such instances, two electrical cable segments are mechanically attached to the dead-end tower under high tension and are electrically connected to form a continuous electrical pathway. As illustrated in FIG. 1, electrical cable segment 11a is secured (e.g., anchored) to dead-end tower 12a using a dead-end termination 13 (e.g., a tension clamp) and is electrically connected to an adjacent electrical cable segment 11b through an electrical jumper 14. The electrical cable segments 11a/11b are insulated from the dead-end tower 12a by an insulator string 15.

Another hardware component that may be used in a transmission line is referred to as a splice. While the length of a single overhead cable segment may be several thousand meters, a transmission line may span several hundred kilometers over which the electrical power must be transmitted. To span these distances, the linemen must often join two cable segments together. In this case, one or more splices may be utilized to join two electrical cable segments, e.g., between two dead-end towers. The splice functions as both a mechanical junction that holds the two ends of the electrical cable segments together and an electrical junction allowing the electric current to flow through the splice. As illustrated in FIG. 1, a splice 16 operatively connects electrical cable segment 17c to electrical cable segment 17d to form a mechanical junction and a continuous electrical pathway.

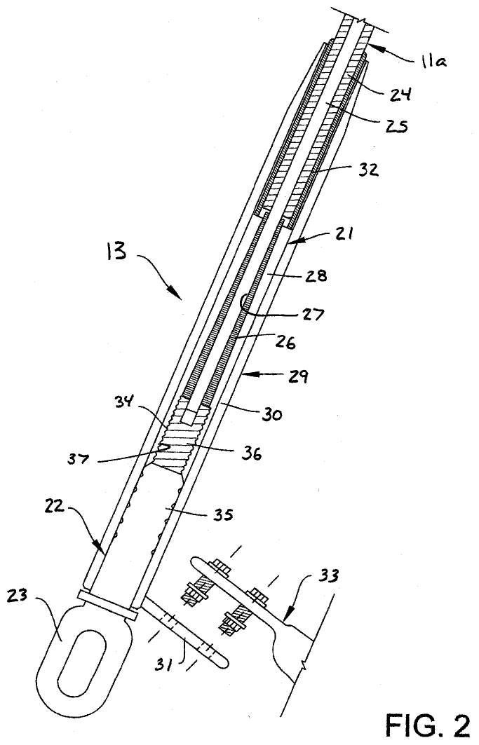

FIG. 2 illustrates a cross-section of an assembled termination apparatus (e.g., a dead-end) such as dead-end 13 in FIG. 1. The dead-end 20 illustrated in FIG. 2 is similar to that illustrated and described in PCT Publication No. WO 2005/041358 by Bryant and in U.S. Pat. No. 8,022,301 by Bryant et al., each of which is incorporated herein by reference in its entirety.

Broadly characterized, the dead-end 13 illustrated in FIG. 2 includes a gripping assembly 21 and a connector 22 for anchoring the dead-end 13, e.g., to a tower as illustrated in FIG. 1, with a fastener 23 disposed at a proximal end of the dead-end 13. At the distal end of the dead-end 13, opposite the fastener 23, the dead-end 13 is operatively connected to an overhead electrical cable segment 11a that includes an electrical conductor 24 (e.g., comprising conductive strands) that surrounds and is supported by a strength member 25 (sometimes referred to as a core), e.g., a fiber-reinforced composite strength member.

The gripping assembly 21 tightly grips the strength member 25 to secure the overhead electrical cable segment 11 to the dead-end 13. As illustrated in FIG. 2, the gripping assembly 21 includes a compression-type fitting (e.g., a wedge-type fitting), specifically a collet 26 having a collet lumen 27 (e.g., a bore) that surrounds and grips onto the strength member 25. The collet 26 is disposed in a collet housing 28, and as the electrical cable segment 11 is tensioned (e.g., is pulled onto support towers), friction develops between the strength member 25 and the collet 26 as the collet is pulled further into the collet housing 28. The conical (outer) shape of the collet 26 and the mating inner funnel shape of the collet housing 28 increase the compression on the strength member 25, ensuring that the strength member does not slip out of the collet 26 and therefore that the overhead electrical cable segment 11 is secured to the dead-end 13.

As illustrated in FIG. 2, an outer sleeve 29 is disposed over the gripping assembly 21 and an end of the electrical cable segment 11a. The outer sleeve 29 includes a conductive body 30 to facilitate a continuous electrical pathway between the electrical conductor 24 and a jumper plate 31. An inner sleeve 32 (e.g., a conductive inner sleeve) may be placed between the conductor 24 and the conductive body 30 to facilitate the electrical connection between the conductor and the conductive body. The conductive body 30 may be fabricated from aluminum and the jumper plate 31 may be welded onto the conductive body, for example. The jumper plate 31 is configured to attach to a connector plate 33 to facilitate the formation of an electrical pathway between the electrical cable segment 11a and another electrical cable segment (not illustrated), e.g., through a jumper cable as illustrated in FIG. 1.

The connector 22 includes a fastener 23 (e.g., an eyebolt) and gripping assembly mating threads 34 disposed at a gripping assembly end 36 of the connector body 35. The gripping assembly mating threads 34 are configured to operatively mate with connector mating threads 37 of the collet housing 28 to facilitate movement of the connector 22 against the collet 26, pushing the collet 26 into the collet housing 28 when the threads 34 and 37 are engaged and the connector 22 is rotated relative to the collet housing 28. This strengthens the compressive grip of the collet 26 onto the strength member 25, further securing the overhead electrical cable 11 to the dead-end 13. The fastener 23 is configured to be attached to a dead-end tower as illustrated in FIG. 1, to secure the dead-end 13 and therefore the electrical cable 11, to the dead-end tower.

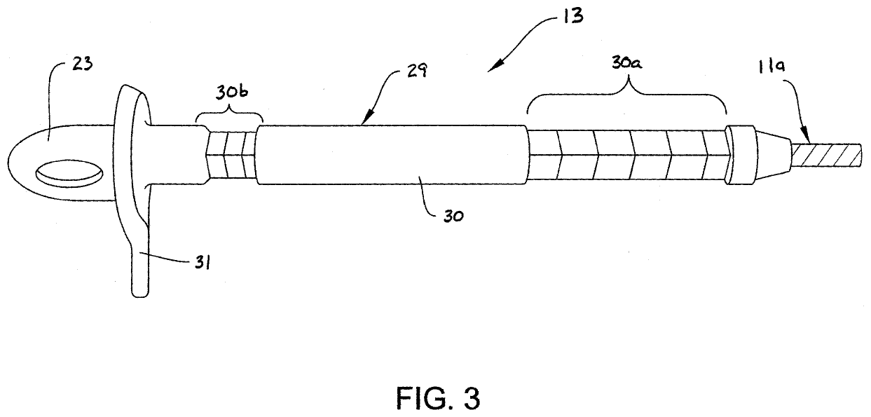

FIG. 3 illustrates a perspective view of the dead-end 13 that has been crimped (e.g., compressed) onto an overhead electrical cable segment 11. The dead-end 13 includes a connector having a fastener 23 that extends outwardly from a proximal end of an outer sleeve 29. A jumper plate 31 is integrally formed with the outer conductive sleeve body 30 for electrical connection to a connection plate as illustrated in FIG. 2. As illustrated in FIG. 3, the outer sleeve body 30 is crimped over (e.g., onto) two regions of the underlying structure, namely crimped sleeve body region 30a and crimped sleeve body region 30b. The crimped sleeve body region 30b is generally situated over an intermediate portion of the underlying connector (e.g., see FIG. 2), and the crimped sleeve region 30a is generally situated over a portion of the electrical cable segment 11a. The compressive forces placed onto the outer sleeve body 30 during the crimping operation are transferred to the underlying components, i.e., to the connector under the crimped region 30b and to a portion of the electrical cable segment 11a under the crimped region 30a to permanently secure the dead-end 13 to the electrical cable segment 11a.

The dead-end broadly described with respect to FIGS. 2 and 3 can be utilized with various bare overhead electrical cable configurations. The dead-end illustrated in FIGS. 2 and 3 is particularly useful with overhead electrical cables having a fiber-reinforced composite strength member. For example, a compression wedge gripping element, e.g., having a collet disposed in a collet housing (e.g., FIG. 2), enables a fiber-reinforced composite strength member to be gripped under a high compressive force without significant risk of fracturing the composite material. However, those of skill in the art will recognize that other configurations for such dead-ends are disclosed in the art and the foregoing illustrations are merely an example of one configuration that may be used to secure an overhead electrical cable segment to a structure such as a support tower.

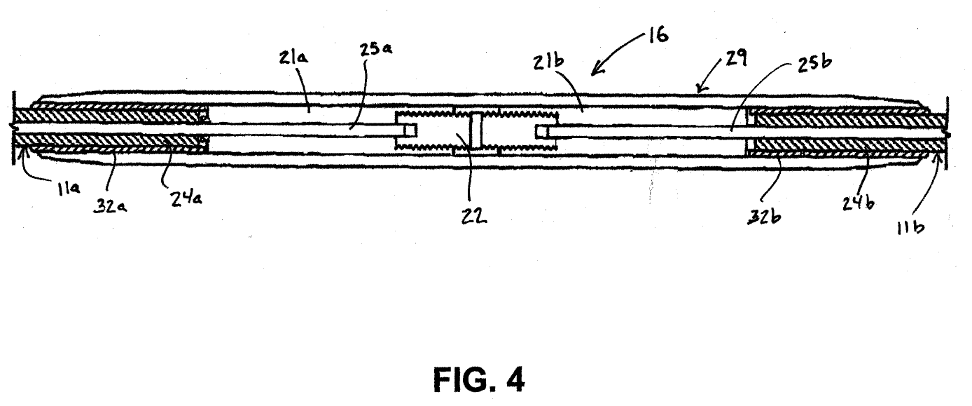

FIG. 4 illustrates a cross-sectional view of a splice 16, e.g., a splice as illustrated in FIG. 1. As shown in FIG. 1, the splice 16 is configured to mechanically and electrically connect two overhead cable segments to form a continuous electrical pathway between the two cable segments. As illustrated in FIG. 4, the splice 16 connects two electrical cable segments 11a and 11b. The splice 16 includes gripping assemblies 21a and 21b that operatively grip electrical cable segments 11a and 11b, e.g., by gripping the strength member segments 25a and 25b. To mechanically join the two electrical cable segments, the gripping assemblies 21a/21b are connected to, e.g., threadably engaged with, a single connector 22. To form a continuous electrical pathway between the electrical cables 11a/11b, e.g., between two electrical conductors 24a/24b, a conductive outer sleeve 29 is placed over the underlying structure and is crimped onto at least the connector body 22 and the ends of the electrical cables 24a and 24b. Conductive inner sleeves 32a/32b may be inserted between the conductors 24a/24b and the outer sleeve 29 to facilitate a robust electrical connection therebetween. As with the dead-ends illustrated above, those of skill in the art will recognize that other configurations for splices are disclosed in the art and the foregoing illustration is merely one example of a splice that may be utilized to connect two electrical cable segments.

The systems and methods disclosed herein may be implemented with electrical lines that incorporate overhead electrical cables having a variety of configurations. One traditional configuration is referred to as aluminum conductor steel reinforced cable (ACSR) cable wherein outer aluminum conductor strands are supported by a strength member having a plurality of steel wires that are twisted, e.g., stranded, together to form the strength member. Other configurations implementing a strength member formed from a plurality of twisted metal wires include aluminum core steel supported (ACSS) cables. These and similar configurations are known to those of ordinary skill in the art.

While the systems and methods disclosed herein may be implemented with electrical lines that incorporate these types of overhead electrical cables, in certain embodiments the systems and methods are particularly useful when the electrical lines incorporate one or more electrical cable segments that utilize a fiber-reinforced composite strength member. As used herein, a fiber-reinforced composite strength member is a strength member that includes an elongate structural element that comprises reinforcing fibers in a binding matrix. Such composite materials offer many benefits including lightweight and advantageous mechanical properties such as a high tensile strength as compared to, for example, steel wires in an ACSR cable. Such a strength member may comprise a single (i.e., no more than one) fiber-reinforced strength element (e.g., a one-piece fiber-reinforced composite strength member), or may be comprised of several fiber-reinforced composite strength elements that are combined (e.g., twisted, stranded or otherwise bundled together) to form the strength member. As such, the present disclosure may use the terms strength member and strength element interchangeably, particularly where the strength member includes a single strength element.

The systems and methods disclosed herein may be utilized with electrical lines having electrical cable segments that incorporate at least one distributed sensing element. A distributed sensing element is an elongate wire or strand that enables location-specific data to be obtained along a length of the distributed sensing element. In one particular characterization, the distributed sensing element comprises at least one optical fiber. As used herein, the term optical fiber refers to an elongate and continuous fiber that is configured to transmit incident light down the length of the optical fiber. Typically, optical fibers include a transmissive core and a cladding layer surrounding the core that is fabricated from a different material (e.g., having a different refractive index) to reduce the loss of light out of the transmissive core and through the exterior of the optical fiber. The optical fibers can be single mode optical fibers or a multimode optical fibers. A single mode optical fiber has a small diameter transmissive core (e.g., about 9 μm in diameter) surrounded by a cladding having a diameter of about 125 μm. Single mode fibers are configured to allow only one mode of light to propagate. A multimode optical fiber has a larger transmissive core (e.g., about 50 μm in diameter or larger) that allows multiple modes of light to propagate. The optical fibers may be fabricated entirely from one or more polymers. However, polymer optical fibers may not have sufficient optical attenuation and adequate heat resistance to withstand manufacture and/or use of the strength member incorporating the optical fiber. In this regard, glass optical fibers are generally preferred for use with electrical cables.

Although the present disclosure contemplates the use of other types of distributed sensing elements, this disclosure will generally refer to the use of optical fibers. However, it is to be understood that the present disclosure is not strictly limited to the use of optical fibers as the distributed sensing element.

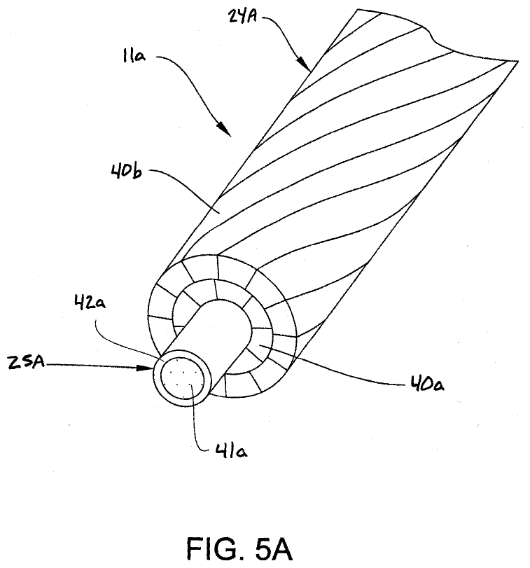

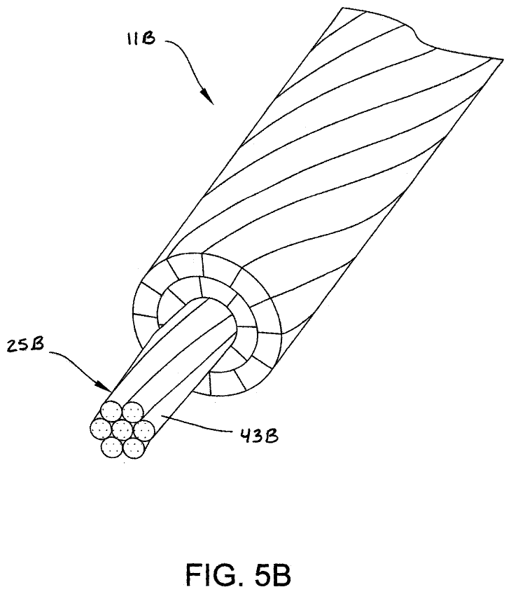

As noted above, overhead electrical cables typically include a central strength member and an electrical conductor disposed around and supported by the strength member. Although the strength member has traditionally been fabricated from steel, such steel strength members are increasingly being replaced by strength members fabricated from composite materials, particularly from fiber-reinforced composite materials, which offer many significant benefits. Such fiber-reinforced composite strength members may include of a single fiber-reinforced composite strength element as is illustrated in FIG. 5A. Alternatively, the composite strength member may be comprised of a plurality of individual fiber-reinforced composite strength elements (e.g., individual rods) that are operatively combined (e.g., twisted or stranded together) to form the strength member, as is illustrated in FIG. 5B. Examples of such multi-element composite strength members include, but are not limited to: the multi-element aluminum matrix composite strength member illustrated in U.S. Pat. No. 6,245,425 by Mccullough et al.; the multi-element carbon fiber strength member illustrated in U.S. Pat. No. 6,015,953 by Tosaka et al.; and the multi-element strength member illustrated in U.S. Pat. No. 9,685,257 by Daniel et al. Each of these U.S. patents is incorporated herein by reference in its entirety. Other configurations for the fiber-reinforced composite strength member may be utilized in the electrical cables.

Referring to FIG. 5A, the overhead electrical cable 11A includes a conductor 24A comprising a plurality of first conductive strands 40a that are helically wrapped around a fiber-reinforced composite strength member 25A, which comprises a single fiber-reinforced composite strength element. A second plurality of conductive strands 40b are helically wrapped around the first conductive strands 40a to increase the volume of the electrical conductor. The conductive strands 40a/40b may be fabricated from conductive metals such as copper or aluminum, and for use in bare overhead electrical cables are typically fabricated from aluminum, e.g., hardened aluminum, annealed aluminum, and/or aluminum alloys. The conductive materials, e.g., aluminum, and do not have sufficient mechanical properties (e.g., sufficient tensile strength) to be self-supporting when strung between support towers, thus necessitating the use of the strength member 25A. In the configuration illustrated in FIG. 5A, the fiber-reinforced composite strength member 25A includes a high tensile strength section 41a (e.g., comprising carbon fibers) surrounded by a galvanic layer 42a that prevents adverse reactions between the carbon in the high tensile strength section 41a and the inner aluminum strands 40a. For example, the galvanic layer 42a may be formed from glass, e.g., glass fibers. The galvanic layer 42a may also be formed from a polymer, such as a thermoplastic, for example.

FIG. 5B illustrates an embodiment of an overhead electrical cable 11B that is similar to the electrical cable illustrated in FIG. 5A. In FIG. 5B, the strength member 25B comprises a plurality of individual fiber-reinforced strength elements (e.g., strength element 43B) that are bundled together to form the strength member 25B. Although illustrated in FIG. 5B as including seven individual strength elements, multi-element strength members may include any number of strength elements that is suitable for a particular application. Although not illustrated in FIG. 5B, the individual strength elements may be formed with carbon fibers and each element may include a galvanic layer as illustrated in FIG. 5A. Alternatively, or in addition to, the strength member 25B, i.e., the bundle of strength elements, may be entirely surrounded by a galvanic layer.

As noted above, the fiber-reinforced composite from which the strength member is fabricated includes reinforcing fibers that are operatively disposed in a binding matrix. The reinforcing fibers may be substantially continuous reinforcing fibers that extend along the length of the fiber-reinforced composite, and/or may include short reinforcing fibers (e.g., fiber whiskers or chopped fibers) that are dispersed through the binding matrix. The reinforcing fibers may be selected from a wide range of materials, including but not limited to, carbon, glass, boron, metal oxides, metal carbides, high-strength polymers such as aramid fibers or fluoropolymer fibers, basalt fibers and the like. Carbon fibers are particularly advantageous in many applications due to their very high tensile strength, and/or due to their relatively low coefficient of thermal expansion (CTE).

The binding matrix may include, for example, a plastic (e.g., polymer) such as a thermoplastic polymer or a thermoset polymer. The binding matrix may also be a metallic matrix, such as an aluminum matrix. One example of an aluminum matrix fiber-reinforced composite is illustrated in U.S. Pat. No. 6,245,425 by Mccullough et al., which is incorporated herein by reference in its entirety. In one particular embodiment, the binding matrix is a thermoset polymer having a glass transition temperature (Tg) that is sufficient to enable the overhead electrical cable to function at normal operating temperatures. For example, the thermoset resin may have a Tg of at least about 130° C., such as at least about 150° C. In some characterizations, the thermoset resin may have a Tg of at least about 170° C., such as at least about 180° C., or even at least about 200° C.

One configuration of a composite strength member for an overhead electrical cable that is particularly advantageous is the ACCC® composite configuration that is available from CTC Global Corporation of Irvine, CA and is illustrated in U.S. Pat. No. 7,368,162 by Hiel et al., noted above. In the commercial embodiment of the ACCC® electrical cable, the strength member is a single element strength member of substantially circular cross-section that includes an inner core of substantially continuous reinforcing carbon fibers disposed in a thermoset polymer matrix. The core of carbon fibers is surrounded by a robust insulating layer of glass fibers that are also disposed in a polymer matrix and are selected to insulate the carbon fibers from the surrounding conductive aluminum strands. See FIG. 5A. The glass fibers also have a higher elastic modulus than the carbon fibers and provide flexibility so that the strength member and the electrical cable can be wrapped upon a spool for storage and transportation.

Although the foregoing characteristics of a fiber-reinforced strength member are disclosed as being desirable for use in an overhead electrical cable, similar characteristics may also be desirable when the strength members disclosed herein are used in other structures, such as bridge cables and messenger cables.

Although not limited thereto, in certain embodiments the systems and methods for operating an overhead electrical line rely upon at least one distributed sensor for the interrogation of an electrical cable. As used herein, a distributed sensor is a sensor that is capable of obtaining data, e.g. making measurements, along a substantially continuous length of the sensor. For example, the distributed sensor may comprise an optical fiber that extends along a length of an electrical cable to enable detection of a temperature and/or strain along the entire length of the electrical cable. As such, the data that is collected and analyzed from the distributed sensor may also include an identification of the location of the measurement along the distributed sensor. In one characterization, the optical fiber is associated with the strength member of at least one of the electrical cable segments. By operatively associating the optical fiber with a strength member, it may be possible to determine certain important properties of the strength member such as the strain that the strength member is experiencing at a particular location along the length of the electrical cable.

In this regard, at least one elongate and continuous optical fiber may be operatively associated with the fiber-reinforced composite strength member. In one configuration, the optical fiber may be embedded within the fiber-reinforced composite (e.g., within the binding matrix). The optical fiber may extend from a first end of the strength member to a second end of the strength member, e.g., such that the entire length of the optical fiber, and substantially the entire length of the overhead electrical cable, may be interrogated using the optical fiber. Through proper selection of the optical fiber and placement of the optical fiber, the strength member and the electrical cable segment can be interrogated to assess the condition of the strength member. Although a single optical fiber may be utilized in an overhead electrical cable, the efficacy of the systems and methods disclosed herein may be improved by including multiple optical fibers, e.g., wherein at least one of the optical fibers is associated with the strength member.

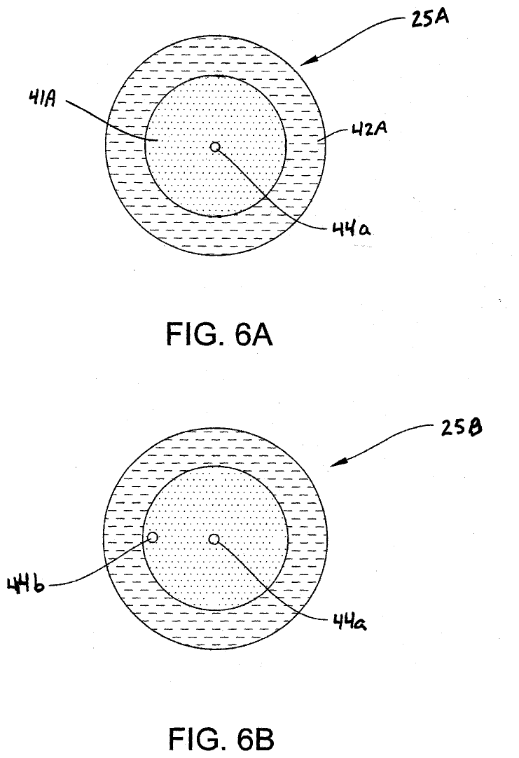

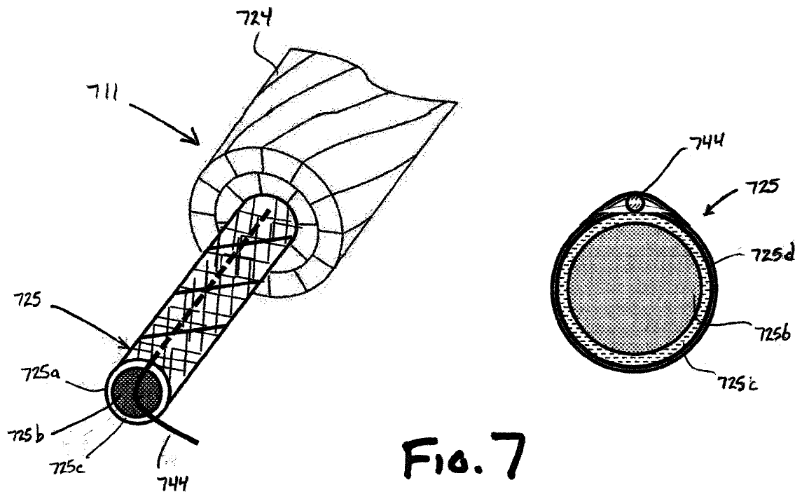

Referring to FIGS. 6A and 6B, cross-sectional views of single element fiber-reinforced composite strength members are illustrated. The configuration of the fiber-reinforced strength members is similar to the strength element illustrated in FIG. 5A. including an inner section of high tensile strength fibers surrounded by an outer layer of an insulative material, e.g., an inner section comprising carbon fibers surrounded by an outer galvanic layer comprising glass fibers. As illustrated in FIG. 6A, the fiber-reinforced composite strength member 25A includes a single optical fiber 44a that is centrally disposed in the strength member 25A, i.e., centrally disposed within the high strength section 41A. Stated another way, the optical fiber 44a is disposed substantially along a longitudinal central axis of the strength member 25A. In the configuration illustrated in FIG. 6B, the strength member is configured in a similar manner as the configuration illustrated in FIG. 6A. As illustrated in FIG. 6B, the strength member 25B includes a second optical fiber 44b in addition to the optical fiber 44a. The optical fiber 44b is offset from the optical fiber 44a, i.e., is offset from a central axis of the strength member 25B. In any event, the placement of at least one optical fiber along a central axis of the strength member may advantageously reduce or eliminate the effect of bending modes upon the optical fiber. Examples of different configurations of optical fibers embedded in the fiber-reinforced composite strength member are illustrated in US Patent Publication No. 2021/0048469 by Dong et al., which is incorporated herein by reference in its entirety.

It will be appreciated that FIGS. 6A and 6B are merely illustrative of possible configurations wherein optical fibers are operatively associated with fiber-reinforced composite strength members. For example, the fiber-reinforced strength members may incorporate more than two optical fibers, such as three, four or more optical fibers. Such additional optical fibers may be used for enhanced measurement sensitivity, for redundancy or for other reasons. In any event, by incorporating at least one optical fiber within the fiber-reinforced composite strength member, e.g., within the binding matrix, certain advantages may be realized. For example, the optical fiber is fully protected (e.g., shielded) from the exterior environment by the binding matrix, ensuring that natural or man-made environmental factors (e.g., impact stresses) will not significantly impair the performance of the sensing optical fiber. Further, the optical fiber is physically and intimately bound to the matrix within the fiber-reinforced composite such that forces that act upon the fiber-reinforced composite strength member (e.g., tensile strain) will be fully and consistently transmitted to the optical fiber along the entire length of the strength member, ensuring accurate measurements.

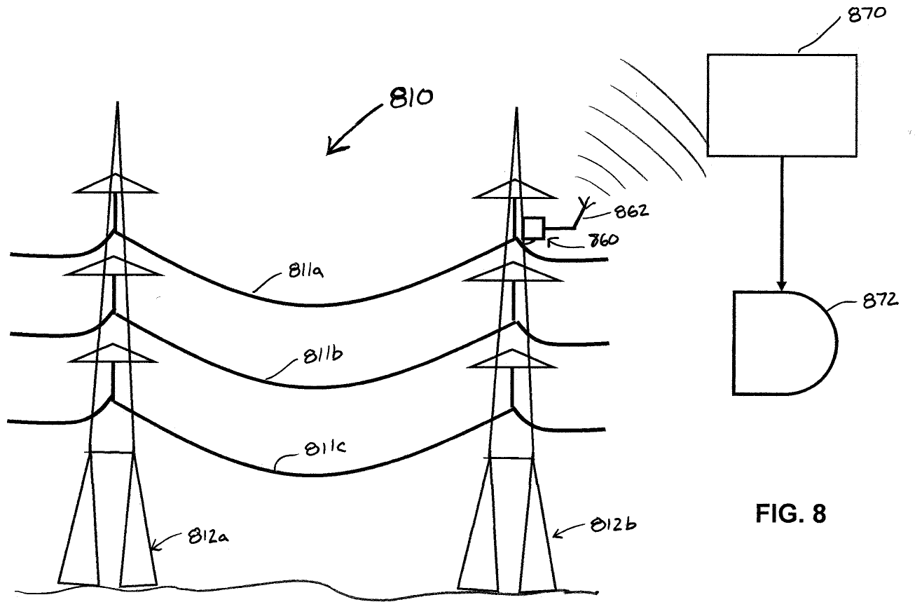

Alternatively, an optical fiber may be associated with a fiber-reinforced strength member, and hence with an electrical cable including the strength member, by alternative means. For example, one or more optical fibers may be affixed to an outer surface of the strength member along the length of the strength member. FIG. 7 illustrates a perspective view of one exemplary embodiment of an overhead electrical cable 711 and a cross-sectional view of the strength member assembly 725 according to this construction. The cable 711 includes a strength member assembly 725 that includes a single strength member 725a having a high tensile strength fiber-reinforced composite core 725b including carbon fibers and a galvanic layer 725c of glass fibers in a binding matrix. An electrical conductor 724 surrounds the strength member assembly 725. In the embodiment illustrated in FIG. 7, the strength member assembly 725 includes an optical fiber 744 that is linearly disposed along an outer surface of the strength member 725a. A tape layer 725d is helically wound around the strength member 725a and the optical fiber 744 to form the strength member assembly 725. Specifically, the tape layer 725d comprises a strip of tape that is helically wound around the strength member 725a in a manner such that the tape overlaps upon itself along seams such that the tape layer 725d covers the entire strength member (e.g., with no substantial gaps) and the optical fiber 744, and such that the tape layer 725d lies between the optical fiber 744 and the electrical conductor 724 along its length. It will be appreciated that the construction illustrated in FIG. 7 is merely exemplary and that optical fibers may be associated with electrical cables using other constructions. Examples of such other constructions are disclosed in PCT Publication No. WO 2021/222663 by Webb et al. which is incorporated herein by reference in its entirety.

The fiber-reinforced strength elements described above may be fabricated by means known to those of skill in the art. In one example, the fiber-reinforced composite strength member is formed by pultrusion process whereby tows of continuous reinforcing fibers (e.g., carbon and glass fibers) are pulled through a binding matrix material (e.g., through an epoxy resin bath), which is subsequently cured to bind the fibers within the matrix and form a fiber-reinforced composite. Optical fibers are provided by the manufacturer in continuous lengths (e.g., of many thousands of meters) on spools in a manner similar to the fiber tows (e.g., carbon fiber tows and glass fiber tows). Therefore, the optical fibers can be integrated into the pultrusion process along with the reinforcing fibers.

One reason that optical fibers are preferable is that devices and methods for collecting distributed data from optical fibers are known in the art. For example, the optical fibers may be operatively coupled to an interrogation device that includes a coherent light source (e.g., a pump laser source) to enable the light to be passed (e.g., pulsed) into the optical fiber in a controlled manner. The light source may be configured to send a signal (e.g., a pulse) down the optical fiber, and the interrogation (e.g., the measurement) of the condition in the optical fiber is performed by analyzing light that is backscattered by the optical fiber. In this regard, the interrogation device may also include a signal detector such as an interferometer, that is configured to detect the backscattered light signals.

For example, the components of the backscattered light can be categorized as Rayleigh components, Brillouin components and Raman components. The backscattered Rayleigh components have the same frequency (i.e., same wavelength) as the primary light source and have a relatively high intensity. The backscattered Rayleigh components can be analyzed to determine the length of the optical fiber by using Optical Time Domain Reflectometry (OTDR). Thus, backscattered Rayleigh components may be used to detect a break in the optical fiber indicating possible damage to the fiber-reinforced composite strength member. However, the backscattered Rayleigh components are not capable of providing any further significant information about the conditions of the optical fiber.

For example, the interrogation device may implement the analysis of at least one of Raman backscattered light components (e.g., a Raman distributed sensor) and Brillouin backscattered light components (e.g., a Brillouin distributed sensor). Both Raman and Brillouin distributed sensor systems make use of a non-linear interaction between the primary light signal and the optical fiber. When a primary light signal of known wavelength is input to an optical fiber, a very small amount of the light signal is scattered back (e.g., a backscattered light signal) at every point along the optical fiber. The backscattered light contains shifted components at wavelengths that are different than the primary light signal. Light components that are shifted to a longer wavelength (i.e., lower energy) are referred to as Stokes components, whereas light components that are shifted to a shorter wavelength (i.e., higher energy) are referred to as Anti-Stokes components. These shifted backscattered light components can be detected and analyzed to ascertain information about the local conditions of the optical fiber, such as its strain and temperature at different points along the length of optical fiber.

In one configuration, at least one of the optical fibers is utilized as a Raman distributed temperature sensor. In a Raman distributed temperature sensor, the interaction between the primary light signal (e.g., the pump laser signal) and optical phonons in the optical fiber material (e.g., silica) creates two backscattered light components in the backscattered light spectrum, Raman Stokes and Raman anti-Stokes. The Raman anti-Stokes component is temperature dependent, i.e., the intensity of the Raman anti-Stokes component increases with increasing temperature of the sensing optical fiber. As a result, the relative intensity of the Raman Stokes and the Raman anti-Stokes backscattered light components can be measured and used to determine a temperature of the sensing optical fiber. The Raman Stokes and Raman anti-Stokes backscattered light components can be detected by a signal detector such as an interferometer or a dispersive spectrometer, which may be a component of the interrogation device.

The position of the temperature reading along the length of the optical fiber can also be determined from the Raman backscattered light components. When a pulsed light signal is used to interrogate the optical fiber, the back-scattered intensity of the Raman Stokes and Raman anti-Stokes backscattered light components can be recorded as a function of time (e.g., “round trip” time), enabling the capture of a temperature profile along the length of the optical fiber, i.e., along the length of the fiber-reinforced composite strength member.

In one example, the optical fiber operatively associated with the fiber-reinforced composite strength member includes a Raman distributed temperature sensor having a multi-mode sensing optical fiber. The multi-mode sensing optical fiber having a high numeric aperture may increase the intensity of the backscattered light which can be important due to the relatively low magnitude of the Raman backscattered light signals.

In another configuration, the interrogation device incorporates Brillouin distributed sensing to interrogate the optical fiber. Brillouin distributed sensors utilize Brillouin backscattering, which is the result of an interaction between the primary light signal and time dependent optical density variations within the optical fiber (i.e., acoustic phonons). The acoustic phonons create a periodic modulation of the refractive index (e.g., the optical density) of the sensing optical fiber material. Brillouin scattering occurs when the propagating primary light signal is diffracted back by this moving “grating,” resulting in a frequency and wavelength shifted component in the backscattered light signal.

As the temperature of the optical fiber increases, the wavelength of the Brillouin backscattered components shifts further away from the primary wavelength. This wavelength shift can be utilized to determine the temperature of the optical fiber. As with a Raman distributed temperature sensor, the location of the temperature reading along the length of the optical fiber can be determined using time of flight information for the backscattered light signal.

Unlike Raman distributed sensors, Brillouin distributed sensors may also be utilized to detect the strain (e.g., tensile strain) in the optical fiber. That is, a change in the strain within the sensing optical fiber will also cause a wavelength shift in the Brillouin backscattered light components due to a change in the optical density of the sensing optical fiber. As a result, the strain that is experienced by the sensing optical fiber at any point along its length can be determined, and hence the strain experienced by the fiber-reinforced composite strength member can also be determined.

Brillouin distributed sensors may be configured to implement a spontaneous Brillouin-based technique, i.e., Brillouin optical time domain reflectometry (BOTDR), or a stimulated Brillouin based technique, i.e., Brillouin optical time domain analysis (BOTDA). One advantage of a BOTDR configuration is that a single coherent pump light source can be utilized, i.e., at one end of the sensing optical fiber. In certain systems, BOTDR also offers the capability of simultaneously measuring the temperature and strain in a single optical fiber. However, the detected backscattered light signal is typically very weak, requiring signal processing and a long integration time.

In another configuration, the Brillouin distributed interrogation device implements a BOTDA technique. In BOTDA, a counter-propagating input light signal (sometimes referred to as a “probe” signal or a “counter wave” signal) having a wavelength difference that is equal to the Brillouin shift is used. This probe signal reinforces the phonon population in the sensing optical fiber, resulting in a higher signal-to-noise ratio. When the primary (pump) light signal is a short pulse, and its reflected intensity is analyzed in terms of flight time and wavelength shift, it is possible to obtain a profile of the Brillouin shift along the length of the sensing optical fiber. BOTDA techniques generally require the two counter propagating light signal wavelengths to be very stable (e.g., synchronized laser sources). Advantageously, a temperature resolution of less than 1.0° C. or even less than 0.5° C. may be achieved. Further, very small strain shifts experienced by the sensing optical fiber may be detected.

Thus, an interrogation device implementing Brillouin distributed sensing is useful for temperature monitoring and is uniquely suited for the measurement of strain. In this regard, it is typically necessary to know the wavelength shift in the optical fiber at a reference temperature in order to calculate the absolute temperature at any point along the optical fiber. It is also typically necessary to know the wavelength shift of the unstrained fiber in order to enable an absolute strain measurement.

According to the present disclosure, the properties of one or more overhead electrical cables may be interrogated (e.g., monitored) during operation of the electrical line, e.g., during operation of the electrical grid, thereby enabling the systems and methods disclosed herein to actively monitor and operate the electrical lines, e.g., in real time on a continuous or semi-continuous basis. Such systems and methods may include the continuous or semi-continuous interrogation of the overhead electrical cables to detect, for example, temperature conditions, strain conditions, mechanical load and/or elongation of the overhead electrical cables and acting in response to certain identified conditions. From a determination of these conditions, other conditions and/or states may be determined, such as the sag of a particular electrical cable segment or the electrical current carried by an electrical cable segment.

Although distributed sensing elements such as optical fibers are preferred for implementing the methods of the present disclosure, the present disclosure is not limited to such devices and systems. For example, in some embodiments, non-distributed sensors may be utilized, either independently or in conjunction with distributed sensors. Non-distributed sensors are sensors that are disposed at intervals along the electrical line, e.g., along an electrical cable. Examples of non-distributed sensors that may be useful for obtaining a temperature of an electrical cable include, but are not limited to, thermocouples and infrared cameras. Further, environmental sensors such as wind stations, humidity sensors and the like may be incorporated to collect data, e.g., for further refinement of the measured values.

It is known that composite strength members that are utilized in electrical cables, i.e., composite cores, may be susceptible to degradation over time. For example, polymers such as thermoset resins may degrade if exposed to elevated temperatures beyond the thermal limits of the polymer. Electrical line operators must be confident that the fiber-reinforced composite core can safely operate at or near its selected continuous use temperature for at least 30 to 50 years, e.g., the expected operational life of the electrical cable.

Therefore, a manufacturer of the composite core and/or the electrical cable must be able to assure the operator that the composite core can safely operate for long periods of time at or near the selected continuous use temperature. One method to determine the life expectancy of a composite core is an accelerated aging test. An accelerated aging test involves aging of composite core samples by exposing the composite cores to elevated temperatures for different periods of time. Data is collected by exposing a plurality of composite core samples to at least two different elevated temperatures, such as three or four different elevated temperatures, for an extended period of time. Periodically, a portion of the composite core samples are removed and a property of the samples, such as the tensile strength, is measured. Once a minimum threshold measurement value is reached, the exposure time period to reach that threshold measurement at each exposure temperature is recorded with the exposure temperature. For example, the minimum threshold measurement may be the point at which the composite core retains 90% of its rated (e.g., unaged) tensile strength. Once the data is plotted, a curve is fit to the measured data points, e.g., an exponential equation is established from the data. The exponential equation can then be used to extrapolate to the amount of time that the composite core can maintain its threshold property value, e.g., 90% of its rated tensile strength, at a selected continuous use temperature for the electrical cable incorporating the composite core.

To perform accelerated age testing, the exposure temperatures during the accelerated aging test must be higher than the selected continuous use temperature. The selected continuous use temperature may range, for example, from about 130° C. to about 250° C., such as from about 150° C. to about 200° C. In the following description, 180° C. is used as the selected continuous use temperature for simplicity, although the methods of the present disclosure are not limited to any particular continuous use temperature.

In one example, composite core samples are exposed to three different temperatures in air circulating ovens under no tension. A schedule is determined for the removal of samples from the ovens for testing. In one particular test protocol, at least three samples are tested after a predetermined exposure time is reached. Once the three samples are removed from the ovens, they are tested for tensile strength and the average, standard deviation and coefficient of variation among the samples are determined. Tensile strength as a function of exposure time for each exposure temperature is recorded. Once the tensile strength of the composite core samples reaches 90% of the rated value for all exposure temperatures, the time vs temperature may be plotted on a semi-log scale. For example, the temperature may be plotted as 1/T, where T is the exposure temperature in Kelvin. Once the points are plotted, a best fit exponential equation may be determined to describe the expected time to reach the minimum threshold value at any given temperature, e.g., at the selected continuous use temperature. The general exponential equation is given below:

$$y = {Ae}^{( B \cdot x )} \qquad ( 1 )$$

$$where :$$

$$e = 2.718 ( Euler ’ s number )$$

$$y = time ( hours ) ;$$

$$A = time ( hours ) , a pre - exponential factor that is a real number ;$$

$$B = represents the degradation energy with temperature ; and$$

$$x = 1 / T , where T is temperature in Kelvin .$$

A and B may be determined from the collected data using a least squared fit methodology of Equation (1). The value of y as a function of x can be plotted on a semi-log plot to form a straight line having a slope B, equal to the degradation energy. The value of the degradation energy B may be used to determine the aging index value, i.e., a value from which the useful lifetime of the composite core, and hence the electrical cable, may be derived. Specifically, a base degradation energy value (B₀) may be calculated, which enables a prediction of the time it will take for the property of interest, e.g., the tensile strength, to drop below a certain minimum acceptance threshold for that value at a selected continuous use temperature.

For example, if composite core samples are placed into three ovens operating at 210° C., 220° C. and 230° C., and once the tensile strength measurements reach the minimum threshold measurement, the semi-log of time as a function of temperature (1/T) can be plotted. The three points can then be fitted using least square fit methodology to determine the coefficients A and B This results in a baseline degradation energy (B₀) which is used as the basis for the aging index.

Once the coefficients of the exponential equation are known, the equation may be extrapolated to the selected continuous operating temperature of the electrical cable, which is less than the temperatures used in the accelerated age testing. At this selected continuous operating temperature, e.g., 180° C., the extrapolated exponential equation will enable calculation of a time that is equivalent to or more than the expected operating life of the electrical cable at this temperature.

However, if the electrical cable is subjected to temporary elevated temperature excursions above the selected continuous operating temperature, these elevated temperature excursions may decrease the expected lifetime of the electrical cable, e.g., the lifetime expected from the baseline exponential equation. Therefore, it would be beneficial to collect temperature data from the electrical cable during operation and recalculate the expected lifetime of the electrical cable by taking into account these elevated temperature excursions.

Accordingly, in one embodiment of the present disclosure, temperature and time data is collected during operation of the electrical line, and this operational data is used to recalculate the expected lifetime of the electrical cable, i.e., the aging index is recalculated. Any temperature and time data that shows operation at or lower than the selected continuous use temperature will not shift the aging index. Once temperatures of greater than the selected continuous use temperature are experienced by the electrical cable, Equation (1) shows that the time at these elevated excursion temperatures exponentially decreases the expected lifetime of the electrical cable. That is, the time that the electrical cable is exposed to these elevated excursion temperatures will reduce the aging index (e.g., reduce the useful lifetime) much faster than the time that the electrical cable is exposed to temperatures at or less than the selected continuous operating temperature.

Since the typical electrical line is expected to be in service for 30, 40 or 50 years, the operational aging index calculations may assume that the exposure time at the selected continuous use temperature forms the basis time and temperature data point, e.g., as is discussed above. From this basis data point and an operational data point collected during operation of the electrical line, a new exponential equation may be determined. For instance, the selected continuous use temperature and selected lifetime of an electrical cable may be 180° C. for 30 years (262,800 hours). Testing at exposure temperatures of 210° C., 220° C. and 230° C. with a minimum threshold measurement value of 90% of the rated tensile strength of the composite core results in a B₀=30.7 and meets a 180° C./30 year selected continuous use temperature. If an elevated temperature excursion to 220° C. is detected for a time period of about 100 hours along the electrical cable, this may decrease the expected lifetime of the electrical cable. To determine the updated aging index, Equation (1) is utilized to calculate a new degradation energy (Bₜ) between the 220° C./100 h excursion data point and the 180° C./262,800 hour basis data point. In this case, the calculated Bₜ is 44.103. From this value, an aging index (AI) can be calculated as follows:

$$A I = ( {B}_{t} - {B}_{o} ) * \frac{100}{{B}_{o}} \qquad ( 2 )$$

That is:

$$Aging Index ( \% ) = ( [ measured B ] - [ basis B ] ) / [ basis B ] \cdot 100$$

Thus, in this example, the updated aging index value would be (44.103−30.7)/30.7·100≈44%. This means that 56% of the life expectancy of the electrical cable has been used due to this single high temperature excursion. It follows that as measured Bₜ approaches B₀, which occurs with increased time at temperatures above 180° C., the aging index will eventually reach 0%, at which time the electrical line operator will need to determine a course of action for the degraded electrical cable.

In another example, a shorter temperature excursion to 200° C. for one hour is detected in the electrical cable and recorded. The new value for degradation energy Bₜ is calculated to be 133.998. The aging index is therefore:

$$( 133.998 - 30.7 ) / 30.7 \cdot 100 = 336 \% .$$

This aging index value is higher than 100%. This demonstrates that the measured degradation energy Bₜ will always be higher than the basis degradation energy B₀ until such time that the elevated temperature excursion(s) produce a Bₜ value that is less than that of the basis value B₀. Thus, to take these aging index numbers into account, the value of the aging index can be limited to start at 100% by the following equation:

$$If ( [ {B}_{t} ] - [ {B}_{0} ] ) / [ {B}_{0} ] \cdot 100 > 100 \% , then return 100 \% , else return ( [ {B}_{t} ] - [ {B}_{0} ] ) / [ {B}_{0} ] \cdot 100$$

Thus, only when the measured Bₜ produces a degradation energy that results in an aging index that is less than 100%, will any future data show a decrease in the aging index to below 100%.

Note that if a 200° C./1 hour data point is collected early in the lifetime of the electrical cable and for the next few years all temperatures measured are at or below the selected continuous use temperature of 180° C., the aging index will remain at 100%. If an elevated temperature excursion occurs at a later time, for example an excursion to 220° C. for 100 hours, this event will trigger a new fit to the measured data points and a new updated aging index value. If this elevated temperature excursion event was the highest temperature event for the next several years, but there are several subsequent temperature excursions to 200° C. for 10 hours more, these subsequent data points will still produce a Bₜ that is higher than the Bₜ calculated for the 220° C./100 hour event. Thus, even several hours more at temperatures of about 200° C. will not further change the updated aging index, and the updated aging index will only change again once temperature excursions in excess of 220° C. are detected, or at 200° C. when the time measured at this temperature produces an updated Bₜ that less than the Bₜ calculated for the 220° C./100 hour elevated temperature excursion event.

In one characterization, the temperature and time data is collected using distributed temperature sensors, e.g., optical fibers associated with the electrical cable that are able to detect temperature and an approximate location associated with the temperature. When distributed sensors are not available to monitor the temperature along the length of the electrical cable, e.g., on a substantially continuous basis, electrical line operators may use other dynamic line rating (DLR) methods to estimate the temperature of the electrical cable. Specifications such as IEEE 738 (https://standards.ieee.org/ieee/738/4997/) specify methods to calculate the temperature of the electrical cable based on a known amperage in the electrical cable, possibly taking into account several environmental inputs such as ambient temperature and/or wind speed. Thus, even without distributed temperature sensors, an electrical line operator may still calculate an updated aging index of the electrical cable using Equation (1).

For instance, an electrical line operator may give an electrical cable a line rating of 2000 amps at 180° C., based upon certain environmental conditions. If an extreme event occurs where the temperature of the electrical cable is higher than the temperature used to rate the capacity of the conductor at 180° C., and the amperage to push through the electrical line needs to be exceeded the highest rating in order to ensure power is still delivered to the load at the end of the line. This can be known as an N−1 or N−2 type event, in which the amperage being pushed through the line exceeds its line rating, and the electrical line operator begins to clock the time at the expected calculated temperature, e.g., 220° C., and the event lasts for 10 hours. Once the extreme event abates, the utility will want to know the aging index of the line.

From Equation (1), and from the example of degradation energy B₀=30.7, and an A₀ calculated to be 1.014×10⁻²⁴, the temperature can be input into the base equation to determine the remining time to the end of the life expectancy at 220° C. In this case, the electrical line operator would calculate that at 220° C., the base equation gives a time of 1100 hours. To calculate an updated aging index based on knowing the time at temperature, the electrical line operator can first calculate the aging time based on the base equation, e.g., 1100 hours, and subtract the assumed time that the electrical cable was at 220° C. using their current line rating methodology, and determine an aging index which may be stated as:

([Time according to base equation at temperature above claimed maximum operating temperature]−[Time assumed using current line rating methodology at the temperature above the claimed maximum operating temperature])/[Time according to base equation at temperature above claimed maximum operating temperature]·100

This will generate a value that starts at 100% and decreases as the time at these elevated temperatures are clocked by the utility using their current line rating methodology. Once a time at these elevated temperatures reaches the allowed time at these elevated temperature, the aging index will become zero and the electrical line operator will need to need to determine a course of action for the electrical cable. Using this methodology for the aging index, only the time/temperature pair that produces the lowest aging index will govern the aging index for the electrical cable.

In another characterization, temperature data for the electrical cable may be determined, in whole or in part, from non-distributed sensors that are associated with the electrical cable. Such non-distributed sensors may include devices such as a thermocouple or an infrared camera that is configured to determine the temperature of the overhead electrical cable at various locations along the length of the electrical cable.

The foregoing describes methods wherein updated aging index values are calculated from the available data, e.g., where new calculations are made in real time from the collected data. Alternatively, updated aging index values can be stored in a reference data table, e.g., a look-up table, containing aging index values in a data matrix, e.g., pre-calculated values can be searched and obtained. The data matrix may be constructed using temperature on one axis and time at temperature on another axis, for example.

In another embodiment, the foregoing methodology may be applied to enable an electrical line operator to make real time decisions about line operating conditions. For example, if a line operator detects an elevated temperature excursion due to environmental or operating conditions, the line operator may consider shutting down, e.g., de-energizing, the electrical line. Before making such a decision, the line operator may wish to calculate the reduction in the expected lifetime of the electrical line, if any, if the elevated temperature excursion is allowed to continue. Also, an operator may determine that the electrical cable has reached its expected lifetime and therefore replace the electrical cable. Similarly, an electrical line operator may wish to determine if intentionally operating the electrical line under elevated temperature conditions, such as by temporarily increasing the amperage, will materially affect the expected lifetime of the electrical cable. The foregoing methods may be used to provide an operator with the expected effect on lifetime, i.e., by enabling hypothetical aging indices to be calculated based on possible future scenarios.

In another embodiment, the foregoing may be applied to a system for the operation of an overhead electrical line. For example, the system configured for the operation an overhead electrical line, where the system includes at least a first overhead electrical cable having a fiber-reinforced composite strength member and an electrical conductor surrounding the fiber-reinforced composite strength member. At least a first optical fiber is associated with the composite strength member, e.g., is embedded within the composite strength member. An interrogation device, such as a BOTDR device, is operatively connected to the at least first optical fiber, and the interrogation device is configured to measure at least one of a temperature and a strain along a length of the composite strength member. A communication link is provided between the interrogation device and a computing device, where the computing device comprises a non-transitory computer readable medium having program instructions executable by a processor to perform an operation using the data collected from the interrogation device. The operation may include instructions to carry out any of the methods described above, e.g., for the calculation of an aging index and/or taking steps in the operation of the electrical line as a result of the aging index calculation. For example, the operation may include determining first temperature data associated with the first overhead electrical cable from the interrogation device, the first temperature data comprising a first temperature value, determining first time period data associated with the first temperature data, the first time period data comprising the approximate amount of time that the electrical cable is exposed to the first temperature value, and calculating a first updated aging index value from a prior aging index value, the first temperature data and the first time period data.

FIG. 8 illustrates an embodiment of such a system for the operation of an overhead electrical line. As illustrated in FIG. 8, a portion of an electrical line 810 is illustrated that includes support towers 812a and 812b. The electrical line 810 includes at least three electrical cables 811a/811b/811c that are supported by the support towers 812a/812b. As disclosed above, each of the electrical cables 811a/811b/811c may include a fiber-reinforced strength member surrounded by an electrical conductor, e.g., surrounded by conductive aluminum strands and one or more optical fibers associated with the electrical cable. An interrogation device such as a BOTDR device 860 is operatively connected to the electrical cable 811a, e.g., is operatively connected to an optical fiber associated with the electrical cable 811a so that the BOTDR device may collect data from the optical fiber relating to temperature and/or strain of the optical fiber. It will be appreciated that more than one interrogation device may be implemented, and/or a single interrogation device may be operatively connected to more than one electrical cable such as by using an optical switch.

As illustrated in FIG. 8, the BOTDR device 860 includes an antenna 862 for establishing a wireless communication link with a computing device 870. The computing device may include program instructions, e.g., on a non-transitory computer readable medium, e.g., a disk drive, solid-state drive or the like. The program instructions are executable by a processor to perform an operation on the data received from the BOTDR device 860, as discussed above. Optionally, the results of the operations performed by the computing device 870 may be output to a display 872, e.g., for review and consideration by an operator, who may institute the performance of actions in response to the data, e.g., in response to a change in the aging index, as is discussed above.

While various embodiments of methods for operating an electrical line by determining a health index have been described in detail, it is apparent that modifications and adaptations of those embodiments will occur to those skilled in the art. However, it is to be expressly understood that such modifications and adaptations are within the spirit and scope of the present disclosure.

What is claimed is:

1. A method for the determination of an aging index associated with an overhead electrical line that is operatively strung onto support towers, the overhead electrical line comprising a first overhead electrical cable having a fiber-reinforced composite strength member and an electrical conductor surrounding the fiber-reinforced composite strength member, the method comprising the steps of:
determining first temperature data associated with the first overhead electrical cable, the first temperature data comprising a first temperature value;
determining first time period data associated with the first temperature data, the first time period data comprising the approximate amount of time that the electrical cable is exposed to the first temperature value; and
determining a first updated aging index value from a prior aging index value, the first temperature data and the first time period data.

2. The method recited in claim 1, wherein upon determining that the first updated aging index value exceeds an acceptable aging index value, providing a system alert to an operator.

3. The method recited in claim 2, wherein the step of providing a system alert comprises providing a system alert on a graphical user interface.

4. The method recited in claim 1, wherein upon determining that the first updated aging index value exceeds an acceptable aging index value, changing an electrical parameter associated with the first overhead electrical cable.

5. The method recited in claim 4, wherein the electrical parameter is the electrical current flowing through the first overhead electrical cable.

6. The method recited in claim 5, wherein the step of changing the electrical current flowing through the first overhead cable comprises stopping the electrical current flowing through the overhead electrical cable.

7. The method recited in claim 6, wherein the step of stopping the electrical current flowing through the first overhead electrical cable comprises shunting at least a portion of the electrical current to a second overhead electrical cable.

8. The method recited in claim 1, wherein upon determining that the first updated aging index value exceeds an acceptable aging index value, updating an operational limit on the overhead electrical cable.

9. The method recited in claim 8, wherein the operational limit is selected from the group consisting of cable temperature and cable current.

10. The method recited in claim 1, wherein upon determining that the first updated aging index value exceeds an acceptable aging index value, calculating an updated expected lifetime for the overhead electrical cable.

11. The method recited in claim 1, wherein the fiber-reinforced strength member comprises reinforcing fibers in a polymer matrix.

12. The method recited in claim 11, wherein the fiber-reinforced strength member comprises reinforcing fibers in a thermoplastic matrix.

13. The method recited in claim 11, wherein the fiber-reinforced strength member comprises reinforcing fibers in a thermoset matrix.

14. The method recited in claim 13, wherein the polymer matrix has a glass transition temperature (Tg) of at least about 150° C.

15. The method recited in claim 11, wherein the fiber-reinforced strength member comprises reinforcing fibers in a metal matrix.

16. The method recited in any one of claims 1 to 15, wherein the fiber-reinforced strength member comprises elongate reinforcing fibers in a matrix.

17. The method recited in claim 16, wherein the elongate reinforcing fibers comprise carbon fibers.

18. The method recited in any one of claims 1 to 17, wherein the first overhead electrical cable has a length of at least about 20 meters.

19. The method recited in claim 18, wherein the overhead electrical cable has a length of at least about 250 meters.

20. The method recited in any one of claims 1 to 19, wherein the prior aging index value is a base aging index value that is calculated before obtaining the first temperature data.

21. The method recited in any one of claims 1 to 20, wherein the step of determining the first temperature data comprises calculating the first temperature value from a known amperage in the first overhead electrical cable.

22. The method recited in any one of claims 1 to 21, wherein the step of determining the first temperature data comprises obtaining the first temperature value from a non-distributed sensor.

23. The method recited in any one of claims 1 to 21, wherein the step of determining the first temperature data comprises obtaining the first temperature value from a distributed temperature sensor associated with the overhead electrical cable.

24. The method recited in any one of claims 1 to 21, wherein the step of determining the first temperature data comprises obtaining first distributed temperature data from a first temperature sensing element that extends along a length of the first overhead electrical cable.

25. The method recited in any one of claim 24, wherein the first temperature sensing element comprises a first optical fiber.

26. The method recited in claim 25, wherein the first optical fiber is a glass optical fiber.

27. The method recited in any one of claims 24 to 26, wherein the first optical fiber is embedded in the fiber-reinforced composite strength member.

28. The method recited in any one of claims 24 to 26, wherein the first optical fiber is affixed to an outer surface of the fiber-reinforced composite strength member.

29. The method recited in any one of claims 24 to 28, wherein the step of obtaining the distributed temperature data from a first temperature sensing element comprises interrogating the first temperature sensing optical fiber using an OTDR device that is operatively connected to the first optical fiber.

30. The method recited in any one of claims 1 to 29, wherein the first temperature data comprises a first time associated with the determination of the first temperature value.

31. The method recited in claim 30, further comprising the step of:
determining second temperature data associated with the first overhead electrical cable, the second temperature data comprising a second temperature value and a second time associated with the second temperature value, wherein the second time is after the first time.

32. The method recited in claim 31, wherein the step of determining first time period data comprises calculating a time period from the first time associated with the first temperature value and from the second time associated with the second temperature value.

33. The method recited in any one of claim 31 or 32, wherein the step of determining the second temperature data comprises obtaining second distributed temperature data from a temperature sensing element that extends along a length of the first overhead electrical cable, wherein the temperature sensing element is an optical fiber.

34. The method recited in claim 33, wherein the temperature sensing element used to obtain the second distributed temperature data is the same temperature sensing element as the first temperature sensing element.

35. The method recited in any one of claims 1 to 34, wherein the first updated aging index value is determined by extrapolating data from a pre-determined baseline data point and a first updated data point that is calculated using the first temperature data and the first time period data.

36. The method recited in claim 35, wherein the first updated data point is calculated using an exponential equation of the form:
$$y = {Ae}^{( B \cdot x )}$$
$$where :$$
$$e = 2.718 ( Euler ’ s number )$$
$$y = time ( hours ) ;$$
$$A = time ( hours ) , a pre - exponential factor that is a real number ;$$
$$B = represents the degradation energy with temperature ;$$
$$x = 1 / T , where T is temperature in Kelvin .$$

37. The method recited in any one of claims 1 to 36, wherein the first updated aging index value is determined from a reference data table.

38. The method recited in any one of claims 31 to 37, further comprising the step of:
determining third temperature data associated with the first overhead electrical cable, the third temperature data comprising a third temperature value and a third time associated with the third temperature value; and
determining a third updated aging index value from the second updated aging index value and the third temperature data.

39. A method for operating an overhead electrical line, the overhead electrical line comprising a first overhead electrical cable having a fiber-reinforced composite strength member and an electrical conductor surrounding the fiber-reinforced composite strength member, the method comprising the steps of:
ascertaining a planned operating temperature and a planned operating time period for the planned operating temperature for the first overhead electrical cable; and
determining an updated health index for the first overhead electrical cable based upon a prior health index, the planned operating temperature and the planned operating time period.

40. A system configured for the operation an overhead electrical line, the system comprising:
at least a first overhead electrical cable having a fiber-reinforced composite strength member and an electrical conductor surrounding the fiber-reinforced composite strength member;
at least a first optical fiber associated with the composite strength member;
an interrogation device operatively connected to the at least first optical fiber and configured to measure at least one of a temperature and a strain along a length of the composite strength member;
a communication link between the interrogation device and a computing device, wherein the computing device comprises a non-transitory computer readable medium having program instructions executable by a processor to perform an operation, the operation comprising:
determining first temperature data associated with the first overhead electrical cable from the interrogation device, the first temperature data comprising a first temperature value;
determining first time period data associated with the first temperature data, the first time period data comprising the approximate amount of time that the electrical cable is exposed to the first temperature value; and
calculating a first updated aging index value from a prior aging index value, the first temperature data and the first time period data.

41. The system recited in claim 40, wherein the operation comprises implementation of the method steps recited in any one of claims 2 to 38.
